(19) United States
(12) Patent Application Publication
(10) Pub. No.: US 2026/0229463 A1
(43) Pub. Date: Aug. 6, 2026

(54) DIVERSION GAS SUPPLY ASSEMBLIES, AND RELATED PROCESSING SYSTEMS, PROCESSING CHAMBERS, AND METHODS

(71) Applicant: Applied Materials, Inc., Santa Clara, CA (US)

(72) Inventors: Lei ZHANG, Santa Clara, CA (US); Xiaosong JI, Saratoga, CA (US); Chen-Ying WU, Santa Clara, CA (US); Eric DAVEY, Mountain View, CA (US); Borui XIA, San Jose, CA (US); Liurui LI, Santa Clara, CA (US); Renzhong DU, San Jose, CA (US); Kiran GARIKIPATI, Gilbert, AZ (US); Somanna MALLANGADA BOSE, San Leandro, CA (US); Raghu Saraneesh ATMAKUR SUBRAMANYA, Santa Clara, CA (US); Jose RUIZ, San Jose, CA (US); Guru DUTT, Milpitas, CA (US); Christophe MARCADAL, Santa Clara, CA (US)

(21) Appl. No.: 19/075,305

(22) Filed: Mar. 10, 2025

Related U.S. Application Data
(60) Provisional application No. 63/752,531, filed on Jan. 31, 2025.

(51) Int. Cl. H01J 37/32

(52) U.S. Cl. CPC H01J 37/32449

(57) ABSTRACT

Embodiments of the present disclosure generally relate to semiconductor processing equipment. In one or more embodiments, a processing system includes a plasma source assembly, an exhaust line operable to exhaust materials, a flow adapter, and a gas supply assembly fluidly connected to the flow adapter. The gas supply assembly includes a first gas source operable to flow a first composition, a first supply valve fluidly between the flow adapter and the first gas source, and a first diverter valve between the exhaust line and an upstream side of the first supply valve. The gas supply assembly includes a second gas source operable to flow a second composition, a second supply valve fluidly between the flow adapter and the second gas source, and a second diverter valve between the exhaust line and an upstream side of the second supply valve.

### CROSS-REFERENCE TO RELATED APPLICATION

This application claims the benefit of U.S. provisional patent application Ser. No. 63/752,531, filed Jan. 31, 2025, which is herein incorporated by reference in its entirety.

### BACKGROUND

### Field

Embodiments of the present disclosure generally relate to semiconductor processing equipment. More particularly, embodiments of the present disclosure relate to a clean chamber (e.g., a pre-clean chamber) and/or chemical vapor deposition (CVD) chamber for semiconductor fabrication. The subject matter can involve in situ dry cleaning methods using the same.

### Description of the Related Art

In the fabrication of electronic devices on semiconductor substrates, a substrate can be positioned on a heated pedestal configured to control the temperature of the substrate. Gases can flow over the substrate to process the substrate, such as to deposit on the substrate, pre-clean the substrate, and/or etch the substrate. However, the gas flows can involve turbulence and/or non-uniformity distributions of flow. Moreover, gas flows can involve delayed gas flows and stabilization, which can hinder processing.

There is a need, therefore, for gas flow arrangements that facilitate quick switching and flows of gases.

### SUMMARY

Embodiments of the present disclosure generally relate to semiconductor processing equipment. More particularly, embodiments of the present disclosure relate to a clean chamber (e.g., a pre-clean chamber) and/or chemical vapor deposition (CVD) chamber for semiconductor fabrication.

In one or more embodiments, a processing system includes a processing chamber that includes a processing volume, a plasma source assembly operable to supply a plasma composition to the processing volume, an exhaust line operable to exhaust the plasma composition from the processing volume, a flow adapter coupled between the processing volume and the plasma source assembly, and a gas supply assembly fluidly connected to the flow adapter. The gas supply assembly includes a first gas source operable to flow a first composition, a first supply valve fluidly between the flow adapter and the first gas source, and a first diverter valve between the exhaust line and an upstream side of the first supply valve. The gas supply assembly includes a second gas source operable to flow a second composition, a second supply valve fluidly between the flow adapter and the second gas source, and a second diverter valve between the exhaust line and an upstream side of the second supply valve.

In one or more embodiments, a gas supply assembly includes a first gas source operable to flow a first composition, a first supply valve fluidly between the flow adapter and the first gas source, and a first diverter valve between the exhaust line and an upstream side of the first supply valve. The gas supply assembly includes a second gas source operable to flow a second composition, a second supply valve fluidly between the flow adapter and the second gas source, and a second diverter valve between the exhaust line and an upstream side of the second supply valve.

In one or more embodiments, a method of substrate processing includes generating a plasma, flowing a first composition through a first diverter line, and flowing the first composition through a first supply line and into a processing volume of a processing chamber. The method includes flowing a second composition through a second diverter line, and flowing the second composition through a second supply line and into the processing volume of the processing chamber. The first composition and the second composition respectively flow to the processing volume for a time period of less than 3.0 seconds.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic cross sectional side view of a processing system, according to one or more embodiments.

FIG. 2 is a schematic side cross-sectional view of a flow assembly, according to one or more embodiments.

FIG. 3 is a schematic circuit diagram view of the gas supply assembly fluidly connected to the processing chamber, according to one or more embodiments.

FIG. 4 is a schematic block diagram view of a method of substrate processing, according to one or more embodiments.

FIG. 5 is a schematic diagram view of a control loop for the gas supply assembly shown in FIG. 3, according to one or more embodiments.

FIG. 6 is a schematic table view of a table showing the turning on and off of the flows of compositions F1-F4 throughout a purge stage, an F1/F2 divert stage, and an F1/F2 supply pulse stage, according to one or more embodiments.

FIGS. 7A-7E are schematic profile views of various pulse implementations for the first composition and the second composition, according to one or more embodiments.

FIG. 8 is a schematic plan view of a system, according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

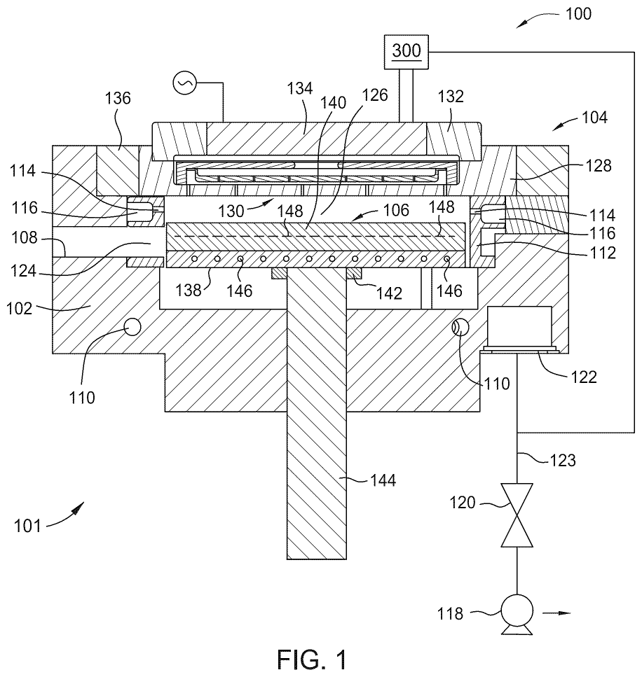

FIG. 1 is a partial schematic cross sectional side view of a processing system 101, according to one or more embodiments. The processing system 101 includes a processing chamber 100, and the processing chamber 100 includes a chamber body 102, a lid assembly 104, and a substrate support 106. In one or more embodiments, the substrate support 106 includes a pedestal. In one or more embodiments, the substrate support 106 includes a ring. The lid assembly 104 is disposed at an upper end of the chamber body 102, and the substrate support 106 is at least partially disposed within the chamber body 102. The lid assembly 104 can be referred to as a lid assembly. The processing chamber 100 and the associated hardware can be formed from one or more process-compatible materials, such as aluminum.

The chamber body 102 includes a slit valve opening 108 formed in a sidewall thereof to provide access to the interior of the processing chamber 100. The slit valve opening 108 is selectively opened and closed to allow access to the interior of the chamber body 102 by a handling robot. A substrate can be transported in and out of the processing chamber 100 through the slit valve opening 108 to an adjacent transfer chamber and/or load-lock chamber, or another chamber within a cluster tool.

In one or more embodiments, the chamber body 102 includes a channel 110 formed therein for flowing a heat transfer fluid therethrough. The heat transfer fluid can be a heating fluid or a coolant and is used to control the temperature of the chamber body 102 during processing and substrate transfer. The temperature of the chamber body 102 can be controlled to prevent unwanted condensation of the gas or byproducts on the chamber walls. Exemplary heat transfer fluids include water, nitrogen gas, ethylene glycol, or a mixture thereof. Other heat transfer fluids are contemplated.

The chamber body 102 also includes a liner 112 that surrounds the substrate support 106. The liner 112 can be removable for servicing and cleaning. The liner 112 can be made of a metal such as aluminum or stainless steel, silicon carbide (SiC), or a ceramic material. The liner 112 can be any process compatible material. The liner 112 can be bead blasted to increase the adhesion of any material deposited thereon, thereby preventing flaking of material which results in contamination of the processing chamber 100. In one or more embodiments, the liner 112 includes one or more apertures 114 and a pumping channel 116 formed therein that is in fluid communication with a vacuum system. The apertures 114 can provide a flow path for gases into the pumping channel 116, which provides an egress for the gases within the processing chamber 100.

The vacuum system can include a vacuum pump 118 and a throttle valve 120 to regulate flow of gases through the processing chamber 100. The vacuum pump 118 and the throttle valve 120 are disposed along an exhaust line 123. The vacuum pump 118 is coupled to a vacuum port 122 disposed on the chamber body 102 and therefore, in fluid communication with the pumping channel 116 formed in the liner 112. An aperture 124 is aligned with the slit valve opening 108 disposed on a side wall of the chamber body 102. The aperture 124 is formed within the liner 112 to allow entry and egress of substrates to/from the chamber body 102. The terms “gas” and “gases” are used interchangeably, unless otherwise noted, and can refer to one or more precursors, reactants, catalysts, carrier, purge, cleaning, etching, combinations thereof, as well as any other fluid introduced into the chamber body 102.

The apertures 114 can allow the pumping channel 116 to be in fluid communication with a processing volume 126 within the chamber body 102. The processing volume 126 can be defined by a lower surface of the lid assembly 104 and an upper surface of the substrate support 106, and can be surrounded by the liner 112. The apertures 114 may be uniformly sized and evenly spaced about the liner 112. Any number, position, size or shape of apertures may be used, and the number, position, size or shape of apertures can vary depending on the flow pattern of gas across the substrate receiving surface as is discussed in more detail below. In addition, the size, number and position of the apertures 114 can be configured to achieve uniform flow of gases exiting the processing chamber 100. The aperture size and location may be configured to provide rapid or high capacity pumping to facilitate a rapid exhaust of gas from the processing chamber 100. For example, the number and size of apertures 114 in closer proximity to the vacuum port 122 may be smaller than the size of apertures 114 positioned farther away from the vacuum port 122.

In operation, one or more gases exiting the processing chamber 100 flow through the apertures 114 formed through the liner 112, and flow into the pumping channel 116. The gas then flows within the pumping channel 116 and through ports into a vacuum channel and exits the vacuum channel through the vacuum port 122 into the vacuum pump 118.

The lid assembly 104 includes a number of components stacked on top of one another, as shown in FIG. 1. In one or more embodiments, the lid assembly 104 includes a lid rim 128, a gas delivery assembly 130, and a top plate 132. The gas delivery assembly 130 is coupled to the lid rim 128 (such as an upper surface of the lid rim 128) and can be arranged to reduce thermal contact with the lid rim 128. The components of the lid assembly 104 can be constructed of a material having a high thermal conductivity and low thermal resistance, such as an aluminum alloy with a highly finished surface for example. The thermal resistance of the components of the lid assembly 104 can be less than about 5×10⁻⁴ m² K/W. The lid rim 128 can hold the weight of the components making up the lid assembly 104 and can be coupled to an upper surface of the chamber body 102 via a hinge assembly to provide access to the internal chamber components, such as the substrate support 106 for example.

The lid assembly 104 includes an electrode 134 to generate a plasma of reactive species within the processing volume 126. In one or more embodiments, the electrode 134 is supported on the top plate 132 and is electrically isolated from the top plate 132. For example, an isolator ring 136 can be disposed about a lower portion of the electrode 134 to separate the electrode 134 from the top plate 132. The isolator ring 136 can be made from aluminum oxide or any other insulative and process compatible material.

In one or more embodiments, the electrode 134 is coupled to a power source and the gas delivery assembly 130 is connected to ground (e.g. the gas delivery assembly 130 can serve as an electrode). Accordingly, a plasma of one or more process gases can be generated in the processing volume 126 and/or within the gas delivery assembly 130.

Any power source capable of activating the gases into reactive species and maintaining the plasma of reactive species may be used. For example, radio frequency (RF), direct current (DC), and/or microwave (MW) based power discharge techniques may be used. The activation may also be generated by a thermally based technique, a gas breakdown technique, a high intensity light source (e.g., UV energy), and/or exposure to an x-ray source. A remote activation source may be used, such as a remote plasma generator, to generate a plasma of reactive species which are then delivered into the processing chamber 100. While the processing chamber 100 is shown and described as a plasma processing chamber, the substrate support 106 as described herein may be utilized in other chambers that are not utilized for plasma processing, such as chemical vapor deposition (CVD) processes.

The substrate support 106 includes a cooling base 138. The cooling base 138 is coupled to a support member 140 and a flange 142 of a stem 144. The cooling base 138 includes a plurality of cooling channels 146 formed therein for flowing a coolant. The support member 140 includes a plurality of heating elements 148. The heating elements 148 can function as a multi-zone heater. The processing system 101 includes a gas supply assembly 300 fluidly connected to the processing chamber 100. The gas supply assembly 300 supplies a plurality of gases to the processing chamber 100.

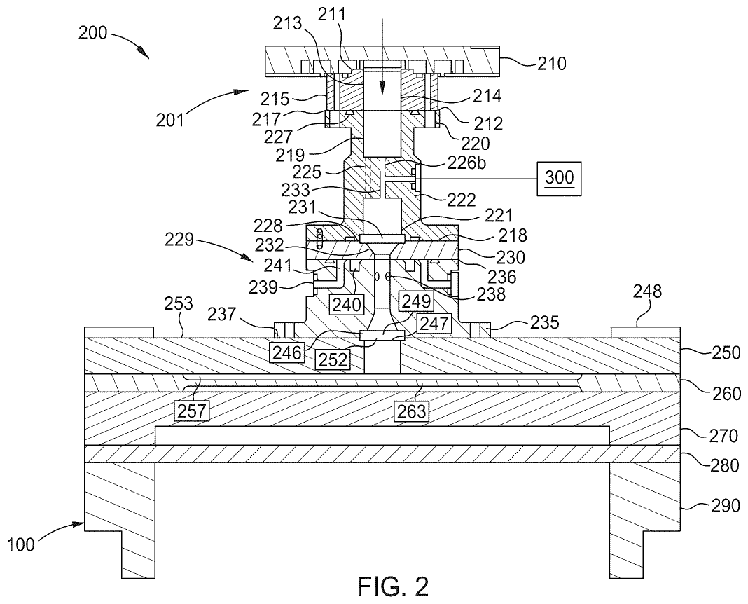

FIG. 2 is a schematic side cross-sectional view of a flow assembly 200, according to one or more embodiments. The flow assembly 200 includes a plasma source 210. At least part of the flow assembly 200 can be used in place of at least part of the lid assembly 104 in FIG. 1. The flow assembly 200 can be coupled to the processing chamber 100 in FIG. 1. The plasma source 210 may be coupled with one or more of an isolator 215, an flow adapter 220, a spacer 230, and a mixing manifold 235. The mixing manifold 235 may be coupled with a top of processing chamber 205, and may be coupled with an inlet to processing chamber 205.

The isolator 215 may be coupled with plasma source 210 at a first end 211, and may be coupled with the flow adapter 220 at a second end 212 opposite the first end 211. Through isolator 215 may be defined one or more flow openings 213, 214. A central flow opening 213 extending through the first end 211 may be used. The central flow opening 213 may transition to smaller flow openings 214 extending from a base of the central flow opening 213 defined within the isolator 215 through second end 212. As an example, one such smaller flow opening 214 is illustrated in FIG. 2 although it is contemplated that any number of smaller flow openings 214 may be used. The isolator 215 may also define one or more trenches defined beneath isolator 215. The trenches may be or include one or more annular recesses defined within isolator 215 to allow seating of an o-ring or elastomeric element, which may facilitate coupling with the flow adapter 220. The various components of the flow assembly 200 can be formed of a metal (such as aluminum or stainless steel), a ceramic, graphite, silicon carbide (SiC), quartz (such as transparent quartz or opaque quartz), and/or other materials. The isolation 215 can be formed of a thermally conductive material to provide a thermal break, isolator 215 may be formed of a less thermally conductive material.

Flow adapter 220 may be coupled with the second end 212 of the isolator 215. Flow adapter 220 can include a first end face 217 and a second end face 218 opposite the first end. Flow adapter 220 may define one or more central cavities through portions of flow adapter 220. For example, from first end face 217, an inlet cavity 219, or a first central channel, may extend at least partially through flow adapter 220 towards second end face 218, and may extend through any length of flow adapter 220. The inlet cavity 219 may extend less than half of a length through flow adapter 220, may extend about half of the length of flow adapter 220, or may extend more than half of the length of flow adapter 220. The inlet cavity 219 (e.g., central channel) may include a diameter of a shape circumscribing the smaller flow openings 214 of isolator 215, such as by having a radius substantially similar to or equivalent to a radius defined from a central axis through isolator 215 and extending to an outer edge of a diameter of the flow openings 214. For example, inlet cavity 219 may have a circular or ovular shape that includes one or more diameters that may extend tangentially with an outer portion of the flow openings 214 of isolator 215.

Flow adapter 220 may define a base of inlet cavity 219 within the flow adapter 220, which may define a transition from inlet cavity 219 to a plurality of flow openings 225 that may at least partially extend through flow adapter 220. The transition may occur at a midpoint through the adapter, which may be at any position along a length of the adapter. For example, second flow openings 225 may extend from a base of inlet cavity 219 towards the second end face 218 of the flow adapter 220, and may extend fully through the second end face 218. In one or more embodiments, the second flow openings 225 may extend through a mid-portion of flow adapter 220 from a first end accessing the inlet cavity 219 to a second end accessing an outlet cavity 221, which may extend into the second end face 218 of the flow adapter 220. The outlet cavity 221 (which can be a second central channel) may have a diameter similar to the inlet cavity 219, or may have a diameter greater than or less than the diameter of the inlet cavity 219. The second flow openings 225 may have a diameter less than or about 50% of a diameter of the inlet cavity 219, and may have a diameter less than or about 40%, less than or about 30%, less than or about 20%, less than or about 10%, less than or about 5%, or less of the diameter of the inlet cavity 219.

Flow adapter 220 may include one or more flow openings 222 (such as one or more ports) formed in an outer surface of the flow adapter 220, such as formed in a sidewall or side portion of the flow adapter 220. The one or more flow openings 222 can respectively flow a gas (such as a precursor) to be mixed with a precursor flowed from the plasma source 210. The gas(es) flowed through the one or more flow openings 222 can flow to an inner flow opening 223 prior to flowing to the outlet cavity 221. In an embodiment where different gases are supplied through different flow openings 222, the gases are mixed in the inner flow opening 223. In the outlet cavity 221 the gas(es) flowing from the inner flow opening 223 (e.g., central flow opening) are mixed with the plasma composition supplied from the plasma source 210 and flowing through the second flow openings 225. The inner flow opening 223 can extend along a central longitudinal axis of the flow adapter 220.

The present disclosure contemplates that the inner opening 223 can extend to the inlet cavity 219 (as shown in ghost with numeral 226b) such that mixing of gases can occur in the inlet cavity 219 (and then flow through the second flow openings 225), in addition to or in place of the mixing in the outlet cavity 221. The present disclosure contemplates that the flow adapter 220 may include any version of the inner opening 223 extending towards the first end face 217 and/or the second end face 218 of flow adapter 220.

Flow adapter 220 may be made of a similar or different material from isolator 215. In one or more embodiments, the flow adapter 220 is formed of a metal (such as aluminum or stainless steel, an oxide thereof, or a treated surface thereof), a ceramic, graphite, silicon carbide (SiC), quartz (such as transparent quartz or opaque quartz), and/or other materials. Interior surfaces of flow adapter 220 may be coated with one or more materials to protect flow adapter 220 from damage that may be caused by the gases flowing therein. For example, the coating may include anodizing, yttrium oxide, and/or barium titanate. The flow adapter 220 may include trenches 227 and 228, which may be annular trenches, and may be configured to seat o-rings or other sealing elements.

The second end face 218 of the flow adapter 220 may optionally include a recess extending into the flow adapter 220, and within which a first baffle plate 231 may be seated. The first baffle plate 231 may optionally be included in some system configurations, and may provide improved mixing of a first precursor and second precursor flowing through flow adapter 220. The first baffle plate 231 may include one or more apertures or channels through which the precursors may flow, which may increase uniformity of mixing of the precursors.

A plate assembly 229 includes a spacer plate 230 that can be coupled to the flow adapter 220. The spacer 230 may be or include ceramic, and may be formed of a similar material as isolator 215 and/or flow adapter 220. Spacer plate 230 may include a central opening 232 therethrough. The central opening 232 (e.g., an aperture) can include a taper. A portion of central opening 232 adjacent the outlet cavity 221 may have a diameter equal to or similar to a diameter of the outlet cavity 221. The plate assembly 229 includes a manifold 235 that may be coupled to the spacer plate 230 at a first end 236 or first surface, and may be coupled with the processing chamber 100 (such as a plate of the lid assembly of the processing chamber 100) at a second end 237 opposite first end 236. The manifold 235 includes a flow opening 238 (such as a central channel), which may extend from first end 236 to second end 237 and may be configured to deliver precursors into the processing chamber 100. The manifold 235 can also flow one or more second gases that can be different in composition than the one or more gas(es) supplied through the one or more flow openings 222. The manifold 235 may provide a second mixing stage. For example, in the manifold 235 the one or more second gases can be mixed with the gas(es) supplied through the one or more flow openings 222 and the plasma composition supplied from the plasma source 210. The one or more second gases flow through one or more side flow openings 239 (e.g., ports) formed in a sidewall of the manifold 235. The manifold 235 may include one or more trenches formed in the first end 236. For example, mixing manifold 235 may define a first trench 240, and a second trench 241, which may provide fluid access from the one or more side flow openings 239 to a central opening 238. For example, the one or more side flow openings 239 may provide fluid connection to one or both trenches 240, 241.

In one or more embodiments, the one or more second gases supplied through a sidewall of the manifold 235 include an inert gas (such as argon), one or more etching precursors (such as one or more hydrogen-containing precursors, one or more fluorine-containing precursors, and/or one or more halogen-containing precursors), one or more selectivity precursors, one or more dopant precursors, and/or one or more other precursor(s). In one or more embodiments, the one or more gases supplied through a sidewall of the flow adapter 220 include an inert gas (such as argon), one or more etching precursors (such as one or more hydrogen-containing precursors, one or more fluorine-containing precursors, and/or one or more halogen-containing precursors), one or more selectivity precursors, one or more dopant precursors, and/or one or more other precursor(s), and the plasma composition supplied from the plasma source 210 include plasma effluents (such as radicals, for example hydrogen radicals). In one or more embodiments, the one or more second gases supplied through a sidewall of the manifold 235 have a different composition than the one or more gases supplied through a sidewall of the flow adapter 220.

By mixing gases (such as precursors, for example etchants) prior to delivery to the processing chamber 100, the flow assembly 200 may provide an etchant having uniform properties prior to being distributed about a chamber and substrate. Additionally, by providing multiple stages of mixing, more uniformity of mixing may be provided for the precursors, which can facilitate uniform and adjustable processing. As an example, processes performed with the present application may have more uniform results across a substrate surface. The illustrated stack of components of the flow assembly 200 may limit particle accumulation by reducing the number of elastomeric seals included in the stack, which may degrade over time and produce particles that may affect processes being performed.

Similar to the first baffle plate 231 described previously, the flow assembly 200 may optionally include a second baffle plate 249, which when included, may be included with or instead of first baffle plate 231. For example, the second baffle plate 249 may be seated in a recess formed in the manifold 235. The second baffle plate 249 may include one or more openings (such as apertures or channels) through which the precursors may flow, which may increase uniformity of mixing of the precursors.

In the implementation shown in FIG. 2, the processing chamber 100 may include a number of components in a stacked arrangement. The processing chamber 100 may include a gasbox 250, a blocker plate 260, a faceplate 270, an optional ion suppression element 280, and a lid spacer 290. The components may be utilized to distribute a precursor or set of precursors through the chamber to provide a uniform delivery of etchants or other precursors to a substrate for processing. The gasbox 250, the blocker plate 260, the faceplate 270, the optional ion suppression element 280, and the lid spacer 290 may be part of a lid assembly of the processing chamber 100. A heater 248 may be configured to heat the processing chamber 100. The heater 248 may be a plate heater or resistive element heater. The blocker plate 260 may includes a plurality of openings 263 (such as apertures) therethrough.

The plate assembly 229 can be coupled to the processing chamber 100. The plasma source 210 and the isolator 215 are part of a plasma source assembly 201. The flow adapter 220 is coupled between the plasma source assembly 201 and the plate assembly 229. The plasma source assembly 201 is operable to supply a plasma composition to the processing volume 126, the flow adapter 220 is operable to supply one or more first gases to the processing volume 126, and the plate assembly 229 (such as the manifold 235) is operable to supple one or more second gases to the processing volume 126.

The gas supply assembly 300 is fluidly connected to the one or more flow openings 222. In one or more embodiments, the flow adapter includes a plurality of flow openings 222 and the gas supply assembly 300 respectively supplies different gases to the respective flow openings 222. The present disclosure contemplates that the gas supply assembly 300 can supply different gases to the same one or more flow openings 222.

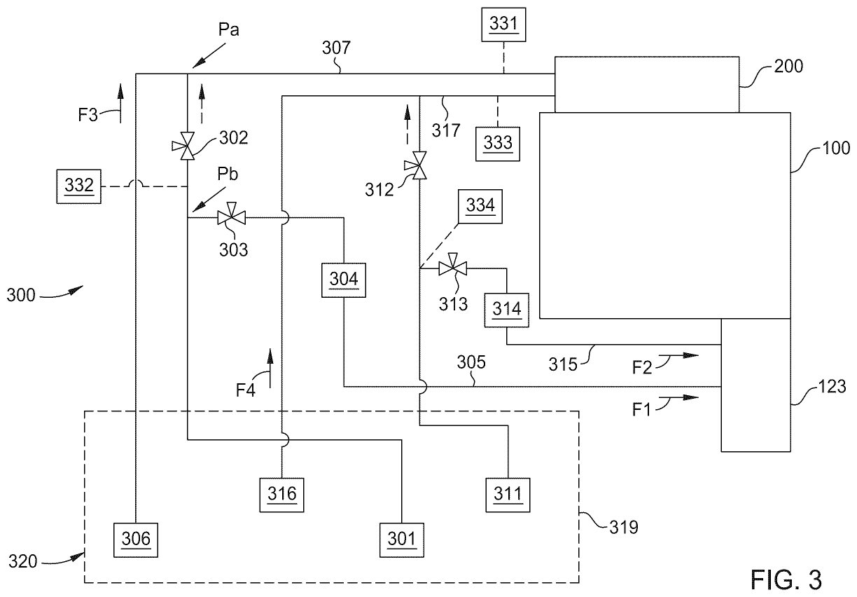

FIG. 3 is a schematic circuit diagram view of the gas supply assembly 300 fluidly connected to the processing chamber 100, according to one or more embodiments.

The gas supply assembly 300 includes a first gas source 301 operable to flow a first composition F1, a first supply valve 302 fluidly between the flow adapter 220 (of the flow assembly 200) and the first gas source 301, and a first diverter valve 303 between the exhaust line 123 and an upstream side of the first supply valve 302. The gas supply assembly 300 includes a first flow adjuster 304 fluidly between the first diverter valve 303 and the exhaust line 123. The first flow adjuster 304 is operable to vary a parameter of the first composition F1 in a first diverter line 305 connected to the exhaust line 123.

The gas supply assembly 300 includes a second gas source 311 operable to flow a second composition F2, a second supply valve 312 fluidly between the flow adapter 220 and the second gas source 311, and a second diverter valve 313 between the exhaust line 123 and an upstream side of the second supply valve 312. The gas supply assembly 300 includes a second flow adjuster 314 fluidly between the second diverter valve 313 and the exhaust line 123. The second flow adjuster 314 is operable to vary a parameter of the second composition F2 in a second diverter line 315 connected to the exhaust line 123. In one or more embodiments, the first flow adjuster 304 and the second flow adjuster 314 respectively include one or more of a motorized needle valve or a solenoid valve (such as a proportional solenoid valve).

The gas supply assembly 300 includes a third gas source 306 operable to flow a third composition F3 to the flow adapter 220 (of the flow assembly 200). The gas supply assembly 300 includes a fourth gas source 316 operable to flow a fourth composition F4 to the flow adapter 220 (of the flow assembly 200). The third gas source 306 is fluidly connected to a first supply line 307 that is fluidly connected to the first supply valve 302 and the flow adapter 220 (of the flow assembly 200). The fourth gas source 316 is fluidly connected to a second supply line 317 that is fluidly connected to the second supply valve 312 and the flow adapter 220 (of the flow assembly 200).

The first supply valve 302 and the second supply valve 312 are disposed outside of a housing 319 of a gas panel 320. In one or more embodiments, the diverter valves 303, 313, the flow adjusters 304, 314, and the diverter lines 305, 315 are disposed outside of the housing 319. The first gas source 301 and the second gas source 311 are disposed within the housing 319. The third gas source 306 and the fourth gas source 316 are disposed within the housing 319. The gas sources 301, 306, 311, 316 respectively include one or more flow controllers, such as one or more flow ratio controllers (FRCs) and/or one or more mass flow controllers (MFCs).

In the orientation shown in FIG. 3, the first gas source 301 flows the first composition F1 and the third gas source 306 flows the third composition F3. The third composition F3 flows to the flow adapter 220 through a first supply line 307. The first supply valve 302 is closed and the first diverter valve 303 is open such that the first composition F1 flows to the exhaust line 123 through the first flow adjuster 304 and the first diverter line 305. The first composition F1 can flow through the first diverter line 305 and the first flow adjuster 304 can be used to optimize and/or stabilize the first composition F1. The first supply valve 302 can be opened, and the first diverter valve 303 can be closed such that the optimized and/or stabilized first composition F1 flows to the first supply line 307, through the flow adapter 202, and through the processing volume of the processing chamber 100.

In the orientation shown in FIG. 3, the second gas source 311 flows the second composition F2 and the fourth gas source 316 flows the fourth composition F4. The fourth composition F4 flows to the flow adapter 220 through a second supply line 317. The second supply valve 312 is closed and the second diverter valve 313 is open such that the second composition F2 flows to the exhaust line 123 through the second flow adjuster 314 and the second diverter line 315. The second composition F2 can flow through the second diverter line 315 and the second flow adjuster 314 can be used to optimize and/or stabilize the second composition F2. The second supply valve 312 can be opened, and the second diverter valve 313 can be closed such that the optimized and/or stabilized second composition F2 flows to the second supply line 317, through the flow adapter 202, and through the processing volume of the processing chamber 100.

The respective flow adjusters 304, 314 can optimize the flow conductance of the respective flows of composition F1, F2 prior to flowing the compositions F1, F2 to the processing volume of the processing chamber 100. For example, a component (such as a stem or another component) of the respective flow adjusters 304, 314 can be adjusted to adjust a pressure (such as a differential pressure) of the respective composition F1, F2 flow. A setting for the composition F1, F2 flow can correspond to an optimized condition, and the setting can be retrieved (such as from a data set, e.g.,, by the controller 190 described below) and applied to the respective flow adjuster 304, 314 prior to flowing the composition F1, F2 to the respective supply line 307, 317 such that the flow is quickly optimized and stabilized for quick and efficient processing. The setting can be determined and/or adjusted, for example by the controller 190 described below. In one or more embodiments, the setting corresponds to one or more of a flow rate or a pressure. As an example, a setting for the respective composition F1, F2 can be applied to the respective flow adjuster 304, 314, and a parameter (such as pressure, flow rate, or another parameter) can be measured at the setting to determine if the parameter is acceptable. If not acceptable, then the setting can be adjusted (such as in a piecemeal manner) until the parameter is acceptable (e.g., until a threshold is reached). Acceptability can be determined by a user and/or the controller 190. Acceptability can be determined by comparing the measured parameter to a reference. The reference can be, for example, a target pressure and/or a target flow rate. The reference can be input or set, for example, using a process recipe.

In one or more embodiments, the setting (which can be retrieved and/or adjusted) for the first flow adjuster 304 corresponds to a pressure P_{b} that is equal to or greater than a downstream pressure Pₐ of the first supply valve 302. As an example, the downstream pressure Pₐ can be the pressure of the third composition F3 flowing on the downstream side of the first supply valve 302. The downstream pressure Pₐ can be measured by a first sensor 331 that is connected to the first supply line 307, and the pressure P_{b} can be measured by a second sensor 332 that is connected to a location upstream of the first supply valve 302. The respective sensors 331-334 can include a pressure sensor (such as a transducer, for example). Other sensors are contemplated.

In one or more embodiments, the setting (which can be retrieved and/or adjusted) for the second flow adjuster 314 corresponds to a pressure that is equal to or greater than a downstream pressure of the second supply valve 312. As an example, the downstream pressure can be the pressure of the fourth composition F4 flowing on the downstream side of the second supply valve 312.

The downstream pressure that is downstream of the second supply valve 312 can be measured by a third sensor 333 that is connected to the second supply line 317, and the pressure upstream of the second supply valve 312 can be measured by a fourth sensor 334 that is connected to a location upstream of the first supply valve 302.

In one or more embodiments, the first composition F1 includes fluorine (such as hydrogen fluoride (HF)) and the second composition F2 includes nitrogen (such as ammonia (NH₃)). The present disclosure contemplates that other elements can be used for the compositions F1, F2. For example, other cleaning elements (such as one or more compositions including chlorine, fluorine, nitrogen, and/or bromine) can be used in the first composition F1 and/or the second composition F2. As an example, the first composition F1 and/or the second composition F2 can include one or more of hydrochloric acid (HCl), hydrofluoric acid (HF), chlorine gas (Cl₂), hydrobromic acid (HBr), chlorine trifluoride (ClF₃), phosphorus trichloride (PCl₃), arsenic trichloride (AsCl₃), sulfuric acid (H₂SO₄), nitric acid (HNO₃), ammonium hydroxide (NH₄OH), and/or germanium tetrachloride (GeCl₄). In one or more embodiments, the third composition F3 and the fourth composition F4 respectively include an inert gas (such as argon (Ar)). The present disclosure contemplates that other elements (such as hydrogen and/or nitrogen) can be used for the compositions F3, F4.

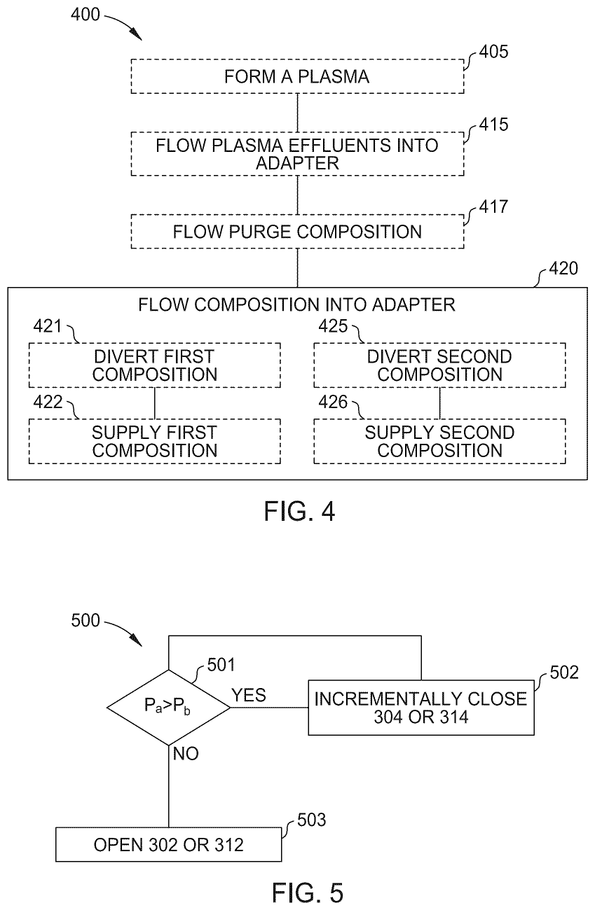

FIG. 4 is a schematic block diagram view of a method 400 of substrate processing, according to one or more embodiments. The method 400 may be conducted in the processing system 101. In an exemplary manner, the method 400 is described in relation to the gas supply assembly 300 and the compositions F1-F4 of FIG. 3. The present disclosure contemplates that other apparatus and/or other compositions can be used for the method 400.

Optional operation 405 includes generating a plasma. As an example, a remote plasma may be generated using a precursor, such as a fluorine-containing precursor. The precursor may be delivered to a remote plasma unit to be dissociated to produce plasma effluents. In one or more embodiments, etchant precursors may be omitted from the remote plasma unit (such as the plasma source assembly 201), which may protect the unit from damage, and allow adjusting of the plasma power to provide specific dissociation of the precursor as may be beneficial to particular processes being conducted.

At optional operation 410, a plasma composition (such as plasma effluents, for example radicals, ions, and/or ionized gases) may be flowed into an adapter (such as the flow adapter 220) coupled to the remote plasma unit (such as the plasma source assembly 201).

At optional operation 415, one or more precursors (such as the first composition F1 and/or the second composition F2) may be flowed into the adapter. The adapter may be configured to provide mixing of the plasma composition and the one or more precursors within the adapter, to produce a first mixture at operation 820, which may be further mixed through a baffle plate as previously described. In one or more embodiments, the one or more precursors include hydrogen and/or one or more halogens. At optional operation 415, one or more plasma effluents may flow into the adapter.

Optional operation 417 includes flowing a purge composition (e.g., the third composition F3 and/or the fourth composition F4) through the respective first supply line 307 or second supply line 317 and into the processing volume at a purge flow rate.

Operation 420 includes flowing one or more compositions (such as the first composition F1 and/or the second composition F2) into the adapter and into the processing volume. Operation 421 includes diverting the first composition, which includes flowing the first composition F1 through the first diverter line 305. The first composition F1 can flow through the first diverter line 305 for a first stabilization period. Operation 422 includes supplying the first composition, which includes flowing the first composition F1 through the first supply line 307 and into the processing volume of the processing chamber 100. Operation 425 includes diverting the second composition, which includes flowing the second composition F2 through the second diverter line 315. The second composition F1 can flow through the second diverter line 315 for a second stabilization period. Operation 426 includes supplying the second composition, which includes flowing the second composition F2 through the second supply line 317 and into the processing volume of the processing chamber 100. The present disclosure contemplates that the diverting (of operations 421, 425) and the supplying (of operations 422, 426) can be part of a pulse, and the pulsing can be repeated. The pulse can be repeated, such as in a plurality of cycles. In one or more embodiments, the processing volume of the processing chamber 100 is maintained at a process temperature of 150 degrees Celsius or less, and a process pressure of 200 Torr or less. Other process temperatures and other process pressures are contemplated.

The first composition F1 and the second composition F2 respectively flow (at operation 422 and operation 426) to the processing volume for a time period of less than 3.0 seconds. In one or more embodiments, the time period is 1.0 seconds or less. In one or more embodiments, the time period is within a range of 0.3 seconds to 0.7 seconds, such as about 0.5 seconds. The first composition F1 and the second composition F2 respectively divert and flow (at operation 421 and operation 425) for a diversion time period of less than 5.0 seconds. In one or more embodiments, the diversion time period is 3.0 seconds or less. In one or more embodiments, the diversion time period is within a range of 1.5 seconds to 2.5 seconds, such as about 2.0 seconds. Other diversion time periods are contemplated.

The first composition F1 and the second composition F2 respectively flow (at operation 422 and operation 426) to the processing volume at a flow rate of at least 100 sccm. In one or more embodiments, the flow rate is within a range of 100 sccm to 1,000 sccm, such as about 400 sccm to about 800 sccm. The first composition F1 and the second composition F2 respectively flow (at operation 422 and operation 426) to the processing volume at a flow rate that is a ratio of the purge flow rate (of operation 417) of the respective third composition F3 or fourth composition F4 with which the first composition F1 or second composition F2 intersects. The ratio is at least 0.10. In one or more embodiments, the ratio is within a range of 0.10 to 0.50.

FIG. 5 is a schematic diagram view of a control loop 500 for the gas supply assembly 300 shown in FIG. 3, according to one or more embodiments.

The control loop 500 is conducted while the respective first composition F1 or second composition F2 flows to the respective first diverter line 305 or second diverter line 315. The control loop 500 can be conducted while the first and second supply valves 302, 312 are closed, the first and second diverter valves 303, 313 are open, and the first and second flow adjusters 304, 314 are at an initially open position. The control loop 500 is used to gradually open/close the respective flow adjuster 304 or 314 to adjust and stabilize the pressure of the respective composition F1 or F2 such that pressure imbalance and/or backflow of the respective composition F3 or F4 is reduced or eliminated when the respective supply valve 302 or 312 is opened to flow the respective composition F1 or F2 to the respective supply line 307 or 317.

At block 501, it is determined whether the downstream pressure Pₐ is greater than the pressure P_{b}. The comparison of the downstream pressure Pₐ with the pressure P_{b} in block 501 can be conducted for the first supply valve 302 to supply the first composition F1 and/or the second supply valve 312 to supply the second composition F2. If the answer to block 501 is “yes,” then the respective flow adjuster 304 or 314 is incrementally closed at block 502. The conduction of block 502 adjusts the pressure P_{b} of the respective composition F1 or F2 to bring the pressure P_{b} closer to the downstream pressure Pₐ. Blocks 501, 502 are repeated to adjust the pressure P_{b} until the pressure P_{b} is equal to or greater than the downstream pressure Pₐ such that the answer to block 501 is “no” for the respective first supply valve 302 or the second supply valve 312. When the answer to block 501 is “no,” the respective supply valve 302 and/or 312 is opened at operation 503 to supply the respective composition F1 and/or F2 to the processing volume of the processing chamber 100. When the answer to block 501 is “no” and the pressure P_{b} is equal to or greater than the downstream pressure Pₐ such that when the respective supply valve 302 or 312 is opened, the respective composition F1 or F2 flows to the respective supply line 307, 317 in a manner with reduced pressure imbalance between first composition F1 and third composition F3, and between second composition F2 and fourth composition F4. Moreover, when the answer to block 501 is “no” the flow of the first composition F1 or the second composition F2 flows to the first supply line 307 or the second supply line 317 with reduced or eliminated backflow of the third composition F3 or the fourth composition F4 to the upstream side of the first supply valve 302 or the second supply valve 312.

The present disclosure contemplates that the pressure P_{b} and the downstream pressure Pₐ can be measured at a variety of locations and/or relative to a variety of valves. For example, the pressure P_{b} and/or the downstream pressure Pₐ can be measured at location(s) within the gas panel 320. As another example, the pressure P_{b} can be measured along the respective diverter line 305, 315, such as between the respective diverter valve 303, 313 and the respective flow adjuster 304, 314, or between the respective flow adjuster 304, 314 and the exhaust line 123.

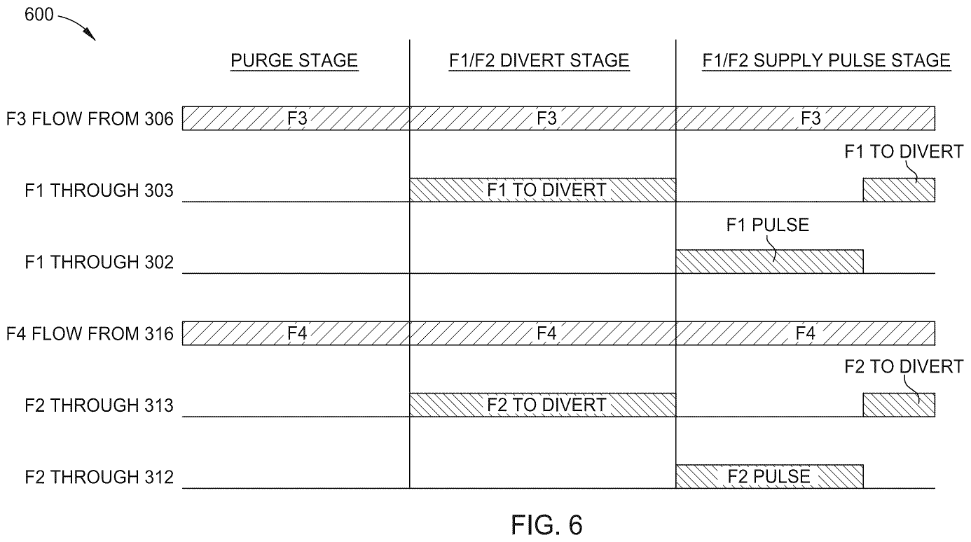

FIG. 6 is a schematic table view of a table 600 showing the turning on and off of the flows of compositions F1-F4 throughout a purge stage, an F1/F2 divert stage, and an F1/F2 supply pulse stage, according to one or more embodiments.

In the purge stage, the third composition F3 flows from the third gas source 306 and the fourth composition F4 flows from the fourth gas source 316. In the F1/F2 divert stage, the first composition F1 flows from the first gas source 301 and to the exhaust line 123 through the first diverter line 305, and the second composition F2 flows from the second gas source 311 and to the exhaust line 123 through the second diverter line 315. In the F1/F2 divert stage, the supply valves 302, 312 are closed and the diverter valves 303, 313 are open. In the F1/F2 supply pulse stage, the first and second compositions F1, F2 are initially pulsed to the processing chamber by opening the supply valves 302, 312 and closing the diverter valves 303, 313. The supply valves 302, 312 are then closed and the diverter valves 303, 313 are opened to divert the first and second compositions F1, F2 to the exhaust line 123 when the pulse is ended.

The present disclosure contemplates that the pulse supply of first composition F1 and the pulse supply of second composition F2 can last for the same amount of time, or for different amounts of time. The present disclosure contemplates that the pulse supply of first composition F1 and the pulse supply of second composition F2 can begin at the same time or different times, and/or can end at the same time or different times.

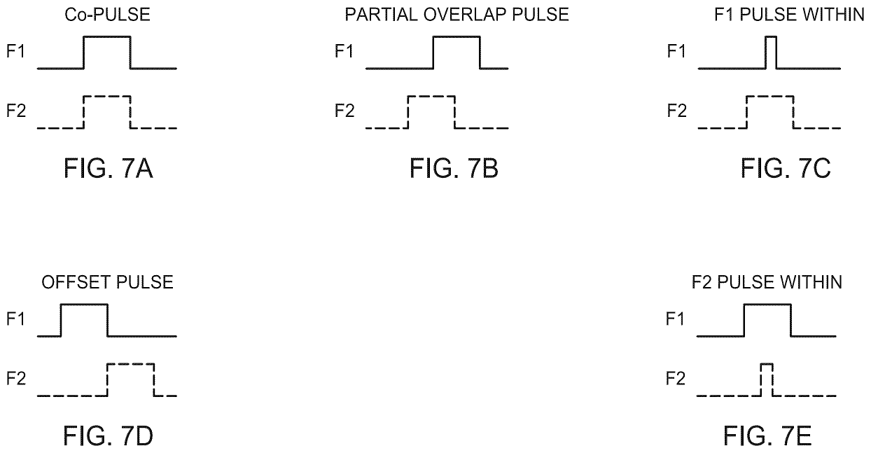

FIGS. 7A-7E are schematic profile views of various pulse implementations for the first composition F1 (e.g., hydrogen fluoride (HF)) and the second composition F2 (e.g., ammonia (NH₃)), according to one or more embodiments.

FIG. 7A shows a co-pulse (e.g., synchronous) implementation where the compositions F1, F2 flow for approximately the same duration and start and end at approximately the same times.

FIG. 7B shows a partial overlap implementation where the flows of the compositions F1, F2 partially overlap with each other.

FIG. 7C shows a pulse within implementation where the flow of the first composition F1 is within and shorter than the flow of the second composition F2.

FIG. 7D shows an offset pulse (e.g., asynchronous) implementation where the flows of the compositions F1, F2 are offset from each other. For example, the flow of one composition F1 or F2 begins upon ending or after ending of the flow of the other composition F2 or F2.

FIG. 7E shows a pulse within implementation where the flow of the second composition F2 is within and shorter than the flow of the first composition F1.

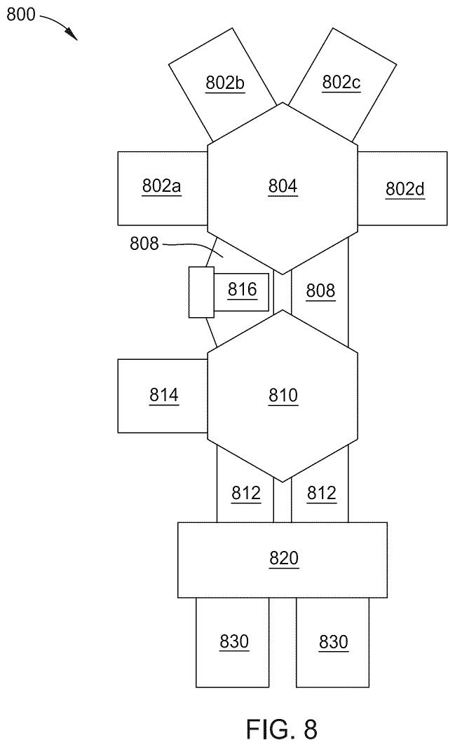

FIG. 8 is a schematic plan view of a system 800, according to one or more embodiments. In one or more embodiments, the system 600 is a cluster tool and/or a vacuum processing system. As shown in FIG. 8, a plurality of processing chambers 802a, 802b, 802c, 802d are coupled to a first transfer chamber 804. The processing chambers 802a-802d may be used to perform any substrate related processes, such as annealing, chemical vapor deposition, physical vapor deposition, epitaxial process, etching process, thermal oxidation or thermal nitridation process, degassing, etc. In one or more embodiments, the processing chamber 802a may be a film formation chamber, such as a vapor phase epitaxy deposition chamber, for example an Epi chamber available from Applied Materials, Santa Clara, California, that is capable of forming a crystalline silicon or silicon germanium. In one or more embodiments, the processing chamber 802a may be an epitaxy deposition chamber such as a single-substrate processing chamber.

The processing chamber 802b may be a rapid thermal processing chamber (RTP). The processing chamber 802c may be a plasma etching chamber or a plasma cleaning chamber. For example the processing chamber 802c may be the processing chamber 100 described in connection with FIGS. 1 and 2. The processing chamber 802d may be a degassing chamber. The first transfer chamber 804 is also coupled to at least one transition station, for example a pair of pass-through stations 806, 808. The pass-through stations 806, 808 maintain vacuum conditions while allowing substrates to be transferred between the first transfer chamber 804 and a second transfer chamber 810. The first transfer chamber 804 has a robotic substrate handling mechanism for transferring substrates between the pass-through stations 806, 808 and any of the processing chambers 802a-802d. The processing chambers 802a-802d are shown configured in a certain order in FIG. 8, but the processing chambers 802a-802d may be configured in any desired order.

One end of the pass-through stations 806, 808 is coupled to the second transfer chamber 810. Therefore, the first transfer chamber 804 and the second transfer chamber 810 are separated and connected by the pass-through stations 806, 808. The second transfer chamber 810 is coupled to a first plasma-cleaning chamber 814, which can be a plasma chamber such as the processing chamber 100 (FIGS. 1 and 2) that is adapted to perform at least some of the operations found in method 400 for removing oxides from a surface of a substrate. In one or more embodiments, the first plasma-cleaning chamber 814 is a Siconi™ or Selectra™ chamber, which is available from Applied Materials, Santa Clara, California.

In one or more embodiments, the at least one transition station, for example one of the pass-through stations 806, 808, is configured to be a plasma-cleaning chamber. Alternatively, a plasma-cleaning chamber may be coupled to one of the pass-through stations 806, 808 for removing contaminants from the surface of the substrate. Thus, the processing system 800 may have a second plasma-cleaning chamber that is, or is connected to, one of the pass-through stations 806, 808. In the implementation shown in FIG. 8, the pass-through station 806 includes a second plasma-cleaning chamber 816. The second plasma-cleaning chamber 816 may be a version of the processing chamber 100 (FIGS. 1 and 2) that is adapted to perform at least some of the operations found in method 400 for removing contaminants from the surface of the substrate. It should be noted that, although one plasma-cleaning chamber 816 is shown coupled to a pass-through station, in this case the pass-through station 806, a plasma-cleaning chamber (e.g., a version of the processing chamber 100) may be coupled to both the pass-through stations 806 and 808.

The second transfer chamber 810 also has a robotic substrate handling mechanism for transferring substrates between a set of load lock chambers 812 and the first plasma-cleaning chamber 814 or the second plasma-cleaning chamber 816. A factory interface 820 is connected to the second transfer chamber 810 by the load lock chambers 812. The factory interface 820 is coupled to one or more pods 830 on the opposite side of the load lock chambers 812. The pods 830 typically are front opening unified pods (FOUP) that are accessible from a clean room.

While two transfer chambers are shown, it is contemplated that any of the transfer chambers may be omitted. In one or more embodiments where the second transfer chamber 810 is omitted, the second plasma-cleaning chamber 816 may be disposed within or coupled to the first transfer chamber 804 at the location currently shown as occupied by the pass-through stations 806 or 808. The first transfer chamber 804 may be coupled to one or more processing chambers capable of forming crystalline silicon or silicon germanium, such as an epitaxy chamber, for example a Centura™ Epi chamber available from Applied Materials, Inc., of Santa Clara, California. Alternatively, the first transfer chamber 804 may be omitted and the second plasma-cleaning chamber 816 may be disposed within or coupled to the pass-through station 806, which is coupled to the second transfer chamber 810. In such a case, the second transfer chamber 810 may be configured to be coupled to one or more processing chambers capable of forming crystalline silicon or silicon germanium.

In operation, substrates are carried from pods 830 to the vacuum processing system 600 in a transport cassette that is placed within one of the load lock chambers 812. The robotic transport mechanism within the second transfer chamber 810 transports the substrates, one at a time, from the load lock chambers 812 to the first plasma-cleaning chamber 814 where the cleaning process, e.g., operations of the method 400, is performed to remove oxides from a surface of a substrate. Once the oxides have been removed from the substrate surface, the robotic transport mechanism disposed within the second transfer chamber 810 transfers the substrate from the first plasma-cleaning chamber 814 to the second plasma-cleaning chamber 816 where a reducing process, e.g., operations of the method 400, is performed to remove contaminants such as carbon or hydrocarbons from the substrate surface. It is contemplated that the steps here may also be performed in the reverse order, e.g., using the robotic transport mechanism to transfer the substrate from the second plasma-cleaning chamber 816 to the first plasma-cleaning chamber 814. In either case, the clean substrates are then transferred by the robotic transport mechanism disposed within the first transfer chamber 804 from the second plasma-cleaning chamber 816 (or the first plasma-cleaning chamber 814) to one or more processing chambers 802a-802d. The one or more processing chambers 802a-802d may include an epitaxy process chamber where a layer formation process, such as the epitaxial deposition is performed.

Upon completion of processing in the one or more processing chambers 802a-802d, the robotic transport mechanism disposed within the first transfer chamber 804 moves the substrate from either one of the processing chambers 802 to the pass-through station 808. The substrate is then removed from the pass-through station 808 by the robotic transport mechanism disposed within the second transfer chamber 810 and transferred to the other load lock chamber 812 through which it is withdrawn from the vacuum processing system 800.

Since the method 400 and/or deposition can be performed within the same system 800, vacuum is not broken as the substrate is transferred among various chambers, which decreases the chance of contamination and improves the quality of the deposited epitaxial film. It should be understood that the movement of the substrates is described herein for illustration purposes. A controller 190 may be used to schedule the movement of the substrates through the vacuum processing system 800 in accordance with a desired sequencing program, which may vary depending upon the application.

Benefits of the present disclosure includes enhanced flow stabilization and reduced turbulence of flow (such as turbulence of etchant gases), fast stabilization of process gases and fast switching of process gases, quick and effective processing. For example, the benefits include effective pre-cleaning (e.g., removing oxide) of bottoms of deep source/drain trenches of high aspect ratio structures on a semiconductor substrate, with reduced or eliminated effects on structure layers (such as reduced or eliminated etching of spacer layers). As another example, the benefits include enhanced processing selectivity (such as etching selectivity) and enhanced control of interfacial contamination.

It is contemplated that one or more aspects disclosed herein may be combined. As an example, one or more aspects, features, components, operations and/or properties of the processing chamber 100, the processing system 101, the lid assembly 104, the flow assembly 200, the plasma source assembly 201, the gas supply assembly 300, the controller 190, the method 400, the control loop 500, the table 600, one or more of the pulse implementations shown in FIGS. 7A-7E, and/or the system 800 may be combined. Moreover, it is contemplated that one or more aspects disclosed herein may include some or all of the aforementioned benefits. As an example, one or more operations of the method 800 can be used in addition to or in place of one or more operations of the method 900.

While the foregoing is directed to embodiments of the present disclosure, other and further embodiments of the disclosure may be devised without departing from the basic scope thereof, and the scope thereof is determined by the claims that follow.

What is claimed is:

1. A processing system comprising:
a processing chamber comprising a processing volume;
a plasma source assembly operable to supply a plasma composition to the processing volume;
an exhaust line operable to exhaust materials from the processing volume;
a flow adapter coupled between the processing volume and the plasma source assembly; and
a gas supply assembly fluidly connected to the flow adapter, the gas supply assembly comprising:
a first gas source operable to flow a first composition,
a first supply valve fluidly between the flow adapter and the first gas source,
a first diverter valve between the exhaust line and an upstream side of the first supply valve;
a second gas source operable to flow a second composition,
a second supply valve fluidly between the flow adapter and the second gas source, and
a second diverter valve between the exhaust line and an upstream side of the second supply valve.

2. The processing system of claim 1, wherein the gas supply assembly further comprises a first flow adjuster fluidly between the first diverter valve and the exhaust line, wherein the first flow adjuster is operable to vary a parameter of the first composition in a first diverter line.

3. The processing system of claim 2, wherein the first flow adjuster includes one or more of a motorized needle valve or a solenoid valve.

4. The processing system of claim 2, wherein the gas supply assembly further comprises a second flow adjuster fluidly between the second diverter valve and the exhaust line, wherein the second flow adjuster is operable to vary a parameter of the second composition in a second diverter line.

5. The processing system of claim 2, further comprising a controller comprising instructions that cause a plurality of operations to be conducted, the plurality of operations comprising:
retrieving a setting from a data set, the setting corresponding to one or more of a flow rate or a pressure;
applying the setting to the first flow adjuster;
flowing the first composition through the first diverter valve and the first flow adjuster for a stabilization period; and
opening the first supply valve and closing the first diverter valve to flow the first composition to the flow adapter.

6. The processing system of claim 2, further comprising a controller comprising instructions that cause a plurality of operations to be conducted, the plurality of operations comprising:
flowing the first composition through the first diverter valve and the first flow adjuster; and
adjusting a setting of the first flow adjuster, while flowing the first composition, until a threshold is reached.

7. The processing system of claim 6, wherein the plurality of operations further comprise:
applying the setting to the first flow adjuster; and
opening the first supply valve and closing the first diverter valve to flow the first composition to the flow adapter.

8. The processing system of claim 6, wherein the setting corresponds to one or more of a flow rate or a pressure.

9. The processing system of claim 6, wherein the setting corresponds to a pressure that is equal to or greater than a downstream pressure of the first supply valve.

10. The processing system of claim 1, wherein the gas supply assembly further comprises:
a third gas source fluidly connected to a first supply line that is fluidly connected to the first supply valve and the flow adapter, the third gas source operable to flow a third composition; and
a fourth gas source fluidly connected to a second supply line that is fluidly connected to the second supply valve and the flow adapter, the fourth gas source operable to flow a fourth composition.

11. A gas supply assembly, comprising:
a first gas source operable to flow a first composition;
a first supply valve fluidly between the flow adapter and the first gas source;
a first diverter valve between the exhaust line and an upstream side of the first supply valve;
a second gas source operable to flow a second composition;
a second supply valve fluidly between the flow adapter and the second gas source; and
a second diverter valve between the exhaust line and an upstream side of the second supply valve.

12. The gas supply assembly of claim 11, wherein the first supply valve and the second supply valve are disposed outside of a housing of a gas panel, and the first gas source and the second gas source are disposed within the housing.

13. The gas supply assembly of claim 11, further comprising a controller comprising instructions that cause a plurality of operations to be conducted, the plurality of operations comprising:
retrieving a setting from a data set, the setting corresponding to one or more of a flow rate or a pressure;
applying the setting to the first flow adjuster;
flowing the first composition through the first diverter valve and the first flow adjuster for a stabilization period; and
opening the first supply valve and closing the first diverter valve to flow the first composition to the flow adapter.

14. The gas supply assembly of claim 11, further comprising a controller comprising instructions that cause a plurality of operations to be conducted, the plurality of operations comprising:
flowing the first composition through the first diverter valve and the first flow adjuster;
adjusting a setting of the first flow adjuster, while flowing the first composition, until a threshold is reached;
applying the setting to the first flow adjuster; and
opening the first supply valve and closing the first diverter valve to flow the first composition to the flow adapter.

15. A method of substrate processing, comprising:
generating a plasma;
flowing a first composition through a first diverter line;
flowing the first composition through a first supply line and into a processing volume of a processing chamber;
flowing a second composition through a second diverter line; and
flowing the second composition through a second supply line and into the processing volume of the processing chamber, the first composition and the second composition respectively flowing to the processing volume for a time period of less than 3.0 seconds.

16. The method of claim 15, wherein the time period is 1.0 second or less.

17. The method of claim 15, wherein the first composition and the second composition respectively flow to the processing volume at a flow rate of at least 100 sccm.

18. The method of claim 17, wherein the flow rate is within a range of 400 sccm to 800 sccm.

19. The method of claim 15, wherein the first gas includes fluoride and the second gas includes nitrogen.

20. The method of claim 15, further comprising flowing a purge composition through the first supply line and into the processing volume at a purge flow rate, wherein the first gas flows to the processing volume at a flow rate that is a ratio of the purge flow rate, and the ratio is at least 0.10.
